(19) United States
(12) Patent Application Publication
(10) Pub. No.: US 2004/0070065 A1
(43) Pub. Date: Apr. 15, 2004

(54) Controlled impedance for wire bonding interconnects

(76) Inventors: Aritharan Thurairajaratnam, San Jose, CA (US); Ramaswamy Ranganathan, Saratoga, CA (US)

Correspondence Address: LSI LOGIC CORPORATION, 1621 BARBER LANE, MS: D-106 LEGAL, MILPITAS, CA, 95035, US

(21) Appl. No.: 10/269,586

(22) Filed: Oct. 11, 2002

(51) Int. Cl. H01L 23/52

(52) U.S. Cl. 257/691

(57) ABSTRACT

A die wire bonded to a semiconductor substrate includes insulated signal wire, insulated power wires and uninsulated ground wires between the die and the semiconductor substrate. A conductive material is provided over the signal, power and ground wire bonds which provides an electrical connection between the uninsulated ground wires. The conductive material follows the same profile as the wire bonds and provides a controlled impedance environment for the signal wirebonds.

### BACKGROUND

The demand for smaller integrated circuits is ever increasing and has lead to an increase in density in these circuits. In particular, the spacing between conductive portions of these integrated circuits has become smaller causing parasitic inductance and capacitance associated with interconnections and contacts to become an increasing problem which leads to incorrect processing of signals.

This invention generally relates to the field of wirebonding. Wirebonding is used to provide connection between integrated circuits and outside leads. More specifically, this invention relates to the methodology to design wirebonds with controlled impedance. By controlling the impedance of the wirebonds, signals can be processed with increased accuracy making the wire bonded circuits of the present invention particularly useful in high speed applications.

Current methods of wirebonding include stitching wirebonds between the bond pad sites on the die to the bond finger/ring sites on the semiconductor package substrate. Because the loop height of the stitches and the proximity of the stitches to power wires and ground wires vary, it is difficult to achieve a controlled impedance environment for the signal wirebond interconnects.

Attempts have been made to provide a controlled impedance environment for the signal wire bond interconnects by providing a metal shield above the wire bonds to achieve controlled impedance. However, this method generally does not work well due to the fact that the profile of the wirebonds is not the same as the profile of the shield.

### OBJECTS AND SUMMARY

It is an object of an embodiment of the present invention is to provide a wirebond for connecting the bond pad sites on a die to the bond sites on a semiconductor package.

Another object of an embodiment of the present invention is to provide a controlled impedance environment for the signal wirebond interconnects.

Briefly, and in accordance with at least one of the foregoing objects, an embodiment of the present invention provides a coated/insulated wirebond for connecting bond pad sites on the die to bond sites on the semiconductor package substrate for signal and power connections. Wirebonds for connecting bond pad sites on the die to bond sites on the semiconductor package for ground connections are not coated or insulated. A conductive material is dispensed over the wirebonds to provide electrical contact between the ground connections. The conductive material follows the same profile as the wire bonds and allows a controlled impedance to be maintained. An encapsulant process may then be performed by dispensing or molding to provide further protection and rigidity to the overall package.

### BRIEF DESCRIPTION OF THE DRAWINGS

The present invention and the advantages thereof will become more apparent upon consideration of the following detailed description when taken in conjunction with the accompanying drawings of which:

FIG. 1 illustrates a cross sectional view of wirebonds which are in accordance with an embodiment of the present invention; and

FIG. 2 is a block diagram representing the steps of a wirebonding method which is in accordance with an embodiment of the present invention.

### DESCRIPTION

While the invention may be susceptible to embodiment in different forms, there are shown in the drawings, and herein will be described in detail, specific embodiments with the understanding that the present disclosure is to be considered an exemplification of the principles of the present invention, and is not intended to limit the invention to that as illustrated and described herein.

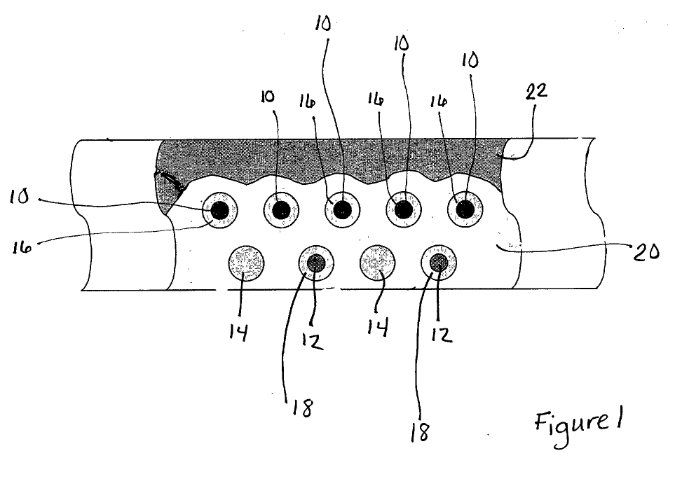

FIG. 1 illustrates wirebond connections which are in accordance with an embodiment of the present invention. The wirebond connections include signal wires 10, power wires 12 and ground wires 14. A coating/insulator 16 is provided over each of the signal wires 10 and a coating/insulator 18 is provided over each power wire 12. Ground wires 14 are not coated/insulated. It is to be understood that the wires and insulators shown in FIG. 1 are not drawn to scale.

A conductive material 20 surrounds the signal 10, power 12 and ground 14 wire bonds. Because no coating/insulator is provided over each of the ground wires 14, the conductive material 20 establishes an electrical connection between the individual ground wires 14. The coating/insulator 16 electrically insulates the signal wires 10 from the conductive material 20, and the coating/insulator 18 electrically insulates the power wires 12 from the conductive material 20.

The conductive material 20 follows the same profile as the wirebonds and allows the impedance surrounding the wire bonds 10, 12, 14 to be controlled. In particular, the impedance surrounding the signal wire bonds 10 can be controlled.

An encapsulant 22 may be provided over the conductive material 20 to provide further protection and rigidity to the overall package.

FIG. 1 illustrates wirebond connections wherein the signal wires 10 and the power wires 12 are insulated while the ground wires are not insulated. It is to be understood that in certain applications the signal wires 10 and the ground wires 14 could be insulated while the power wires 12 are not insulated.

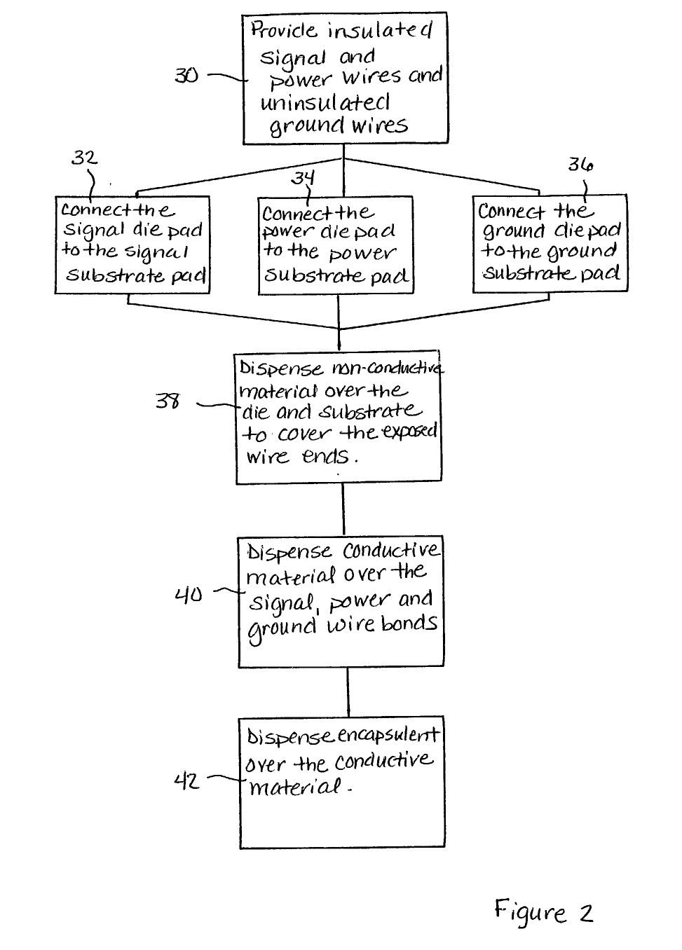

As shown in FIG. 2 a wirebonding method in accordance with an embodiment of the present invention provides the following steps. The process begins by providing an insulated signal wire, an insulated power wire and an uninsulated ground wire (box 30 in FIG. 2). Next, connections are formed between the signal bond pad sites on the die and the signal bond sites on the semiconductor substrate using the insulated signal wire (box 32 in FIG. 2). To form an electrical connection between the insulated signal wire 10 and the bond pad site on the die and the bond site on the substrate, the insulation 16 must be removed from the ends of the insulated signal wire 10. Connections are then formed between the power bond pad sites on the die and the power bond sites on the semiconductor substrate using the insulated power wire 12 (box 34 in FIG. 2). To form an electrical connection between the insulated power wire 12 and the bond pad site on the die and the bond site on the substrate, the insulation 18 must be removed from the ends of the insulated power wire 12. Next, connections are formed between the ground pad sites on the die and the ground bond sites on the semiconductor substrate (box 36 in FIG. 2). It is to be understood that the steps shown in boxes 32, 34, and 36 in FIG. 2 can occur in any order or any of these steps can occur simultaneously.

After the signal, power and ground connections have been made between the die and the semiconductor substrate, a non-conductive material is dispensed over the die and substrate covering the exposed ends of the signal wire 10 and the power wire 12 (box 38 in FIG. 2). Covering the exposed ends of the signal wire 10 and the power wire 12 where the insulation was removed in order to provide connection to the die and the substrate will prevent shorting.

After dispensing the non-conductive material, a conductive material is dispensed over the signal, power and ground wire bonds (box 40 in FIG. 2). Finally, an encapsulant may be provided over the conductive material (box 40 in FIG. 2). The encapsulant may either be dispensed over the conductive material or it may be provided using molding techniques.

It is also to be understood that alternatively the wires to be provided can be insulated signal and ground wires and uninsulated power wires. In this alternative process, the insulation will be removed from the ends of the signal and ground wires in order to provide connection to the die and the substrate. Also, in this alternative process, dispensing of the non-conductive material will cover the exposed ends of the signal and ground wires to prevent shorting.

The method of the present invention provides an electrical connection between the individual ground wire bonds while insulating the signal and power wire bonds. Dispensing the conductive material over the wirebonds allows the conductive material to follow the same profile as the wirebonds and allows the impedance surround the wire bonds to be controlled. In particular, the impedance surrounding the signal wire bonds can be controlled.

While embodiments of the present invention are shown and described, it is envisioned that those skilled in the art may devise various modifications of the present invention without departing from the spirit and scope of the appended claims.

What is claimed is:

1. A method of wirebonding a die to a semiconductor substrate including the steps of:
providing at least one insulated signal wire;
providing at least one insulated power wire;
providing at least one uninsulated ground wire;
connecting said at least one insulated signal wire between the die and the semiconductor substrate;
connecting said at least one insulated power wire between the die and the semiconductor substrate;
connecting said at least one uninsulated ground wire between the die and the semiconductor substrate; and
dispensing a conductive material around said at least one insulated signal wire, said at least one insulated power wire and said at least one uninsulated ground wire.

2. The method of claim 1, further including the steps of:
removing the insulation from the ends of said at least one insulated signal wire, prior to connecting said at least one insulated signal wire;
removing the insulation from the ends of said at least one insulated power wire, prior to connecting said at least one insulated power wire; and
dispensing a non-conductive material over the ends of said at least one insulated signal wire and over the ends of said at least one insulated power wire prior to dispensing the conductive material.

3. The method of claim 1, further including the step of:
providing an encapsulant over said conductive material.

4. A method of wirebonding a die to a semiconductor substrate including the steps of:
providing at least one insulated signal wire;
providing at least one insulated ground wire;
providing at least one uninsulated power wire;
connecting said at least one insulated signal wire between the die and the semiconductor substrate;
connecting said at least one insulated ground wire between the die and the semiconductor substrate;
connecting said at least one uninsulated power wire between the die and the semiconductor substrate; and
dispensing a conductive material around said at least one insulated signal wire, said at least one insulated ground wire and said at least one uninsulated power wire.

5. The method of claim 4, further including the steps of:
removing the insulation from the ends of said at least one insulated signal wire, prior to connecting said at least one insulated signal wire;
removing the insulation from the ends of said at least one insulated ground wire, prior to connecting said at least one insulated ground wire; and
dispensing a non-conductive material over the ends of said at least one insulated signal wire and over the ends of said at least one insulated ground wire prior to dispensing the conductive material.

6. The method of claim 4, further including the step of:
providing an encapsulant over said conductive material.

7. A die wirebonded to a semiconductor substrate comprising:
at least one insulated signal wire connecting a signal die pad to a signal substrate pad;
at least one insulated power wire connecting a power die pad to a power substrate pad;
at least one uninsulated ground wire connecting a ground die pad to a ground substrate pad; and
a conductive material surrounding said at least one insulated signal wire, said at least one insulated power wire, and said at least one uninsulated ground wire.

8. A die wirebonded to a semiconductor substrate as defined in claim 7, further comprising:
an encapsulant over said conductive material.

9. A die wirebonded to a semiconductor substrate comprising:
at least one insulated signal wire connecting a signal die pad to a signal substrate pad;
at least one insulated ground wire connecting a power die pad to a power substrate pad;
at least one uninsulated power wire connecting a ground die pad to a ground substrate pad; and
a conductive material surrounding said at least one insulated signal wire, said at least one insulated ground wire, and said at least one uninsulated power wire.

10. A die wirebonded to a semiconductor substrate as defined in claim 9, further comprising:
an encapsulant over said conductive material.
